(19) United States
(12) Patent Application Publication
(10) Pub. No.: US 2019/0085445 A1
(43) Pub. Date: Mar. 21, 2019

(54) METHOD AND INSTALLATION FOR COATING A SCALED HOT-ROLLED STRIP

(71) Applicant: SMS group GmbH, Duesseldorf (DE)

(72) Inventor: Markus JAENECKE, Solingen (DE)

(21) Appl. No.: 16/194,698

(22) Filed: Nov. 19, 2018

Related U.S. Application Data
(63) Continuation of application No. PCT/EP2017/060638, filed on May 4, 2017.

(30) Foreign Application Priority Data
May 25, 2016 (DE) 102016209093.3
May 30, 2016 (DE) 102016223743.8

(51) Int. Cl. C23C 14/56; B21B 1/28; B21B 45/06; C23C 2/40; C25D 7/06; C23G 3/02

(52) U.S. Cl. CPC C23C 14/562; B21B 1/28; C23G 3/027; C23C 2/40; C25D 7/0614; B21B 45/06

(57) ABSTRACT

The invention relates to a method and an installation for coating a scaled hot-rolled strip (10). The method comprises at least the following steps: (i) providing a hot-rolled strip (10) in the form of a hot-rolled preliminary strip, (ii) preparing the surfaces of the hot-rolled strip (10), and (iii) coating of the hot-rolled strip (10) on at least one prepared surface thereof, wherein the coating is carried out at a temperature of ≤100° C. and immediately after the descaling of the hot-rolled strip (10).

### RELATED APPLICATIONS

This application is a continuation application of International Application PCT/EP2017/060638 filed on May 4, 2017 and designating the USA which claims priority of German applications DE 10 2016 209 093.3 filed May 25, 2016 and DE 10 2016 223 743.8 filed May 30, 2016, all three applications are incorporated herein by reference thereto.

### BACKGROUND OF THE INVENTION

### 1. Field of the Invention

The invention relates to a method and an installation for coating a scaled hot-rolled strip.

In the production of galvanized strips, it is known in the prior art to pickle a hot-rolled preliminary strip on a pickling line. The pickling serves to remove scale or oxide layers from the surfaces of the hot-rolled strip. The removal of such layers serves to prepare for cold rolling and/or to apply a protective layer, e.g. by galvanizing, which serves the corrosion protection of the surface of the hot-rolled strip.

For galvanizing the surfaces of a hot-rolled strip, it is known, e.g., in hot dip galvanizing, to heat the hot-rolled strip initially in a continuous furnace to a temperature of about 500° C., then to pass the hot-rolled strip through a bath melt of molten zinc (at about 450° C.). As soon as the hot-rolled strip leaves the bath melt, the coating thickness for the zinc is adjusted by means of air-jet nozzles.

The galvanizing of hot-rolled strip on the principle of hot dipping or hot dip galvanizing has the disadvantage that in this case the strip surface of the hot-rolled strip is heated significantly above 400° C. As a result of this heat treatment, the hot-rolled strip loses part of its material properties previously set in the hot rolling mill.

### 2. Description of the Prior Art

From EP 0 863 222 A1, it is known to permanently couple the pickling and galvanizing process with a cold rolling process in a whole installation in a continuous line. Here, the hot-rolled strip is always subjected to cold rolling in addition to galvanizing, to bring the hot-rolled strip to a desired finished thickness. Carrying out cold rolling has the disadvantage that the hot-rolled strip solidifies and/or loses its preset material properties. The material properties of the hot-rolled strip must then be restored in a subsequent annealing process.

Accordingly, the invention is based on the object to apply a metal layer on scaled hot-rolled strips in one process step, with preset material properties of the hot-rolled strip should not be lost.

### SUMMARY OF THE INVENTION

This object is achieved by a method for coating a scaled hot-rolled strip, that comprises at least the following steps:
(i) providing a hot-rolled strip in the form of a hot-rolled preliminary strip,
(ii) preparing the surfaces of the hot-rolled strip, and
(iii) coating the hot-rolled strip on at least one prepared surface thereof, wherein the coating is carried out at a temperature of ≤100° C. and immediately after the descaling of the hot-rolled strip, wherein, after step (iii), at least one further treatment step
(iv) is carried out for the hot-rolled strip, in which the hot-rolled strip is provided with an additional coating consisting of a plastic film lamination.

Likewise, the invention provides for an installation for coating a scaled hot-rolled strip, comprising a continuous treatment line, in which the hot-rolled strip is moved in a direction of movement, wherein in the treatment line a pickling device for preparing the surfaces of the hot-rolled strip and at least one first coating device are provided. A coating can be applied to at least one prepared surface of the hot-rolled strip by means of the first coating device, e.g., in the form of a zinc layer. For this purpose, the first coating device is, when in use, configured such that the coating of the hot-rolled strip takes place on at least one side thereof at a temperature of ≤100° C. Furthermore, a second coating device is provided which—as viewed in the direction of movement of the hot-rolled strip—is arranged downstream of the first coating device, wherein an additional coating consisting of a plastic film lamination is applied on at least one surface of the hot-rolled strip by means of the second coating device.

The invention is based on the essential finding that a hot-rolled strip in the course of its coating retains or does not lose its material properties previously set in a hot rolling mill, because all processes according to the present invention occur at low temperatures ≤100° C. In other words, the preset material properties of a hot-rolled strip remain for the most part during pickling and subsequent coating, e.g. galvanizing. A hot-rolled strip is placed directly after the hot rolling mill on the treatment line of the installation according to the invention, and there prepared in a continuous process with respect to its surfaces, e.g., descaled, and then a metallic layer is applied. Of particular importance for the practice of the invention is that a coating of the hot-rolled strip is carried immediately after its surface(s) has/have been prepared for coating, e.g. by an upstream pickling. In any case, the hot-rolled strip is not subjected to any processes, e.g., in the form of cold rolling or the like in which the preset material properties of the hot-rolled strip would be changed or adversely affected.

The usual intermediate transports, intermediate storage, intermediate treatments of the surface, additional strip connections and additional scrap cuts can be dispensed with in carrying out the present invention.

In an advantageous embodiment of the invention, in step (i) of the method, the preparation of the surfaces of the hot-rolled strip is carried out by means of a pickling device. This has the advantage that not only the scale layers formed during hot rolling but also an oxide layer formed on the hot-rolled strip are effectively removed from the surfaces of the hot-rolled strip.

In an advantageous embodiment of the invention, the coating of the hot-rolled strip can be carried out by means of the first coating device according to the principle of electrolysis. This applies in particular to step (iii) of the method according to the invention. Alternatively, it is also possible to carry out the coating of the hot-rolled strip by means of the first coating device according to the principle of a physical vapor deposition (=PVD principle; =physical vapor deposition). Conveniently, the coating of the hot-rolled strip is done on one or both surfaces thereof, i.e., at the top and/or the bottom thereof.

In an advantageous embodiment of the invention, the hot-rolled strip trimmed at its side margins before its surfaces are prepared for the subsequent coating. This ensures a clean coil with defined and coated side margins. Such trimming of the hot-rolled strip may be carried out by a shear arranged upstream of the pickling device—as viewed in the direction of movement of the hot-rolled strip within the treatment line.

Since a further additional coating in the form of a plastic film lamination is applied to the hot-rolled strip following the coating of the hot-rolled strip, the surfaces of the hot-rolled strip are also effectively protected against environmental influences. For this purpose—as viewed in the direction of movement of the hot-rolled strip within the treatment line—a film laminating machine is arranged downstream of the first coating device by means of which the hot-rolled strip is laminated with a plastic film. Additionally, it can also be provided to provide the hot-rolled strip on at least one surface with a roll coating, e.g., by contact with corresponding rollers, which are soaked with a medium which is to be applied to at least one surface of the hot-rolled strip. For example, the hot-rolled strip can be provided with an acrylic coating and/or with a chromatic coating or the like.

In an advantageous embodiment of the invention can be provided that a predetermined roughness is set for the hot-rolled strip on the surfaces thereof. For this purpose—as viewed in the direction of movement of the hot-rolled strip within the treatment line—skin pass mill is arranged downstream of the first coating device, through which skin pass mill the hot-rolled strip is passed. In this regard, it should be noted that when introducing a desired roughness into the surfaces of the hot-rolled strip its preset material properties are not lost.

In an advantageous embodiment of the invention can be provided to apply an oiling on at least one surface of the hot-rolled strip. For this purpose, it is expedient, in particular downstream of the second coating device, to provide an oiling machine by means of which oiling can be applied to a top and/or to a bottom of the hot-rolled strip

In an advantageous embodiment of the invention can be provided for the installation according to the invention that—if necessary—the first coating device is not put into operation when the hot-rolled strip is moved or transported through the treatment line. In this way, it is possible for the hot-rolled strip to undergo only the pickling, but without galvanizing the hot-rolled strip thereafter. By such a shutdown of a sub-process, in the example mentioned said galvanizing by means of the first coating device, the possible product range for the hot-rolled strip can be increased. Thus, for example, pickling of normal steel strips with pickling acid to produce a pickled and oiled strip surface is possible by shutting off the first coating device for applying a zinc coating. This means that use of the installation according to the invention is also possible if the first coating device remains offline.

Further advantages of the invention consist of the following aspects:
saving on investment costs,
energy saving,
higher output,
very short production time,
reduction of logistic operations,
reduction of storage areas,
high flexibility despite a process combination in the treatment line of the installation.

### DETAILED DESCRIPTION OF THE PREFERRED EMBODIMENT

Exemplary embodiments of the invention are described in detail with reference to a schematically simplified drawing, where

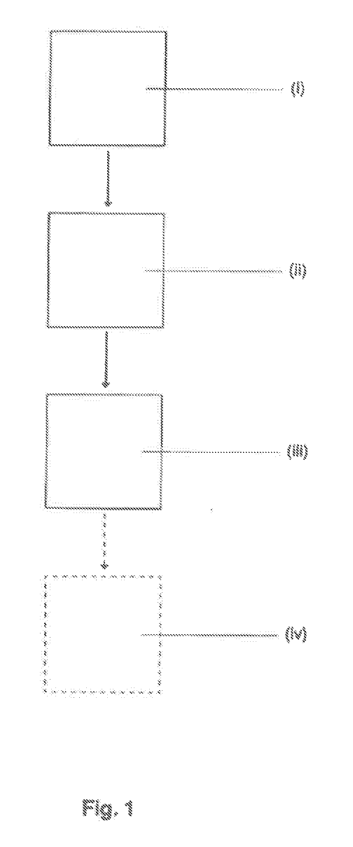

FIG. 1 is a schematically simplified flow diagram for carrying out a method according to the present invention,

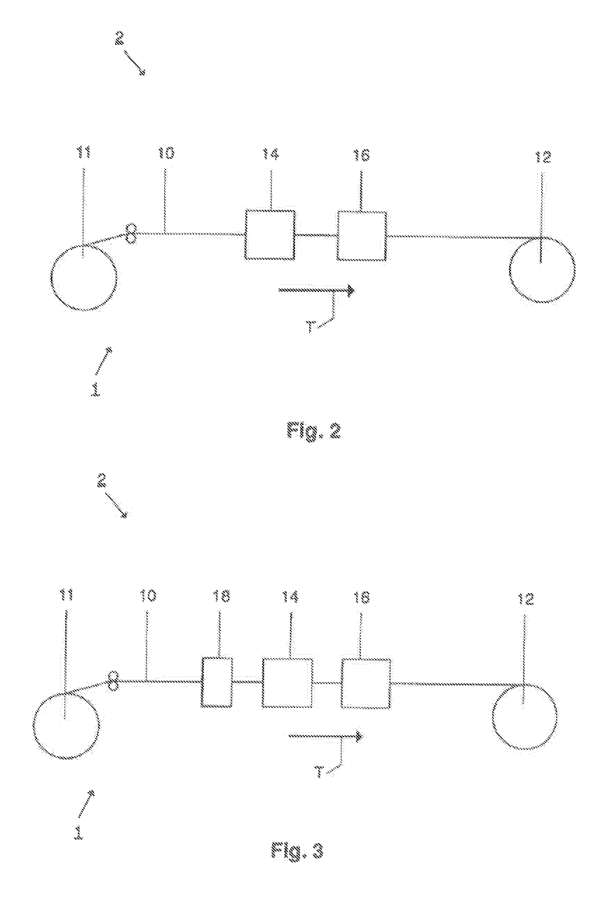

FIG. 2 is a schematically simplified side view of an installation according to the invention according to a first embodiment of the invention, and

FIG. 3-9 are each schematically simplified side views of an installation according to further embodiments of the invention.

The present invention provides a method and an installation for coating a scaled hot-rolled strip on at least one surface thereof.

FIG. 1 illustrates a flow chart of essential steps of the method according to the invention:

First, in a step (i), a hot-rolled strip 10 is provided. Such a hot-rolled strip is a hot rolled preliminary strip which has obtained predetermined material properties during upstream rolling in a hot rolling mill.

Subsequently, in a step (ii), the surface of the hot-rolled strip 10 is subjected to a pre-treatment to prepare the application of a coating thereon. Such pretreatment may consist of pickling the surface(s) of the hot-rolled strip. Here, the hot-rolled strip is passed through a corresponding pickling device, which is explained elsewhere below.

In a next step (iii), the hot-rolled strip 10 is then coated on at least one surface thereof. Regarding this process step, it is separately emphasized at this point that the coating of the hot-rolled strip 10 is carried out at moderate temperatures, i.e. at a temperature of ≤100° C. Due to this relatively low temperature, it is ensured that preset material properties of the hot-rolled strip are preserved.

Optionally, after step (iii), a further method step (iv) may also be provided, which is illustrated by dashed lines in FIG. 1. In this further method step, an additional coating can be applied to the hot-rolled strip, e.g., in the form of a plastic film lamination and/or in the form of a chemical coating or the like, which is applied by suitable rollers on a surface of the hot-rolled strip. Additionally and/or alternatively, it can also be provided to apply an oiling to at least one surface of the hot-rolled strip in the further process step (iv), e.g., by spraying, rolling or electrostatically.

FIGS. 2 to 9 show various embodiments of an installation 1 according to the invention, by means of which a treatment of a scaled hot-rolled strip 10 is possible. In the drawing, the same features for the installation 1 are each provided with the same reference numerals.

FIG. 2 shows the installation 1 according to a first embodiment, in a schematically greatly simplified side view. The installation comprises a treatment line 2, in which a hot-rolled strip 10 is first unwound from a first coiling device 11, wherein the hot-rolled strip 10 at the end of the treatment line 2 is then wound up again by a second coiling device 12. Within the treatment line 2, the hot-rolled strip 10 is moved or transported in a direction of movement T, namely from the first coiling device 11 towards the second coiling device 12.

In the treatment line 2 are arranged a pickling device 14 and—downstream thereof—a first coating device 16. The coating device 16 can be switched on or off as needed, which will be explained separately below.

By treating the hot-rolled strip 10 in the pickling device 14, its surfaces are suitably prepared to subsequently apply a coating to at least one surface of the hot-rolled strip 10, preferably both surfaces thereof, by means of the first coating device 16. The first coating device 16 may be an electrolytic immersion bath in which the surfaces of the hot-rolled strip 10 are galvanized.

After the surfaces of the hot-rolled strip 10 in the treatment line 2 have been pickled and then at least one surface of the hot-rolled strip 10 has been provided with a coating, e.g., with a zinc layer, the hot-rolled strip 10 is then wound up again by the second coiling device 12. In this way, a metallic coating of scaled hot-rolled strip 10 is achieved at only low temperatures, without the material properties of the hot-rolled strip 10 being changed or adversely affected.

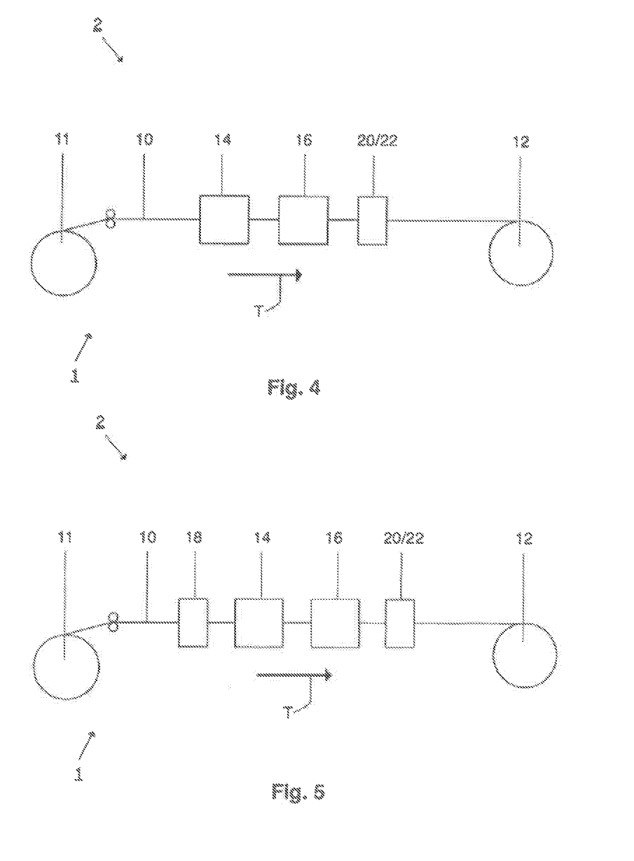

FIG. 3 shows an installation 1 according to the invention in accordance with a further embodiment. Here, in comparison with the embodiment of FIG. 2—as viewed in the direction of movement T of the hot-rolled strip 10—a first shear 18 are arranged upstream of the pickling device 14. This first scissors 18 serves to selectively and definedly trim side margins of the hot-rolled strip 10 so that it is possible to wind up a “clean” coil with defined side margins on the second coiling device 12. FIG. 4 shows an installation 1 according to the invention according to a further embodiment. Here—as viewed in the direction of movement T of the hot-rolled strip 10—a skin pass mill 22 and a second coating device 20 are arranged downstream of the first coating device. Optionally, a stretch leveler 23 may also be arranged between the skin pass mill 22 and the second coating device 20. The second coating device 20 may be a film laminating machine, by means of which the hot-rolled strip 10 is provided with a plastic film lamination. Alternatively, on at least one surface, preferably on both surfaces of the hot-rolled strip 10, i.e., the top and bottom thereof, another coating can be applied by means of the second coating means 20, e.g., a roll coating in the form of a chemical coating or the like, which is applied on the surfaces of the hot-rolled strip 10 by suitable contact rollers.

The skin pass mill 22 serves to provide the surfaces of the hot-rolled strip 10 with a defined roughness, without causing a reduction in thickness of the hot-rolled strip 10 and losing its preset material properties.

FIG. 5 shows an installation 1 according to the invention according to a further embodiment. Upstream of the pickling device 14, a first shear 18, and downstream of the first coating device 16, a second coating device 20 and/or a skin pass mill 22 are arranged. To avoid repetition reference is made to the relevant explanation of FIG. 3 and FIG. 4, respectively.

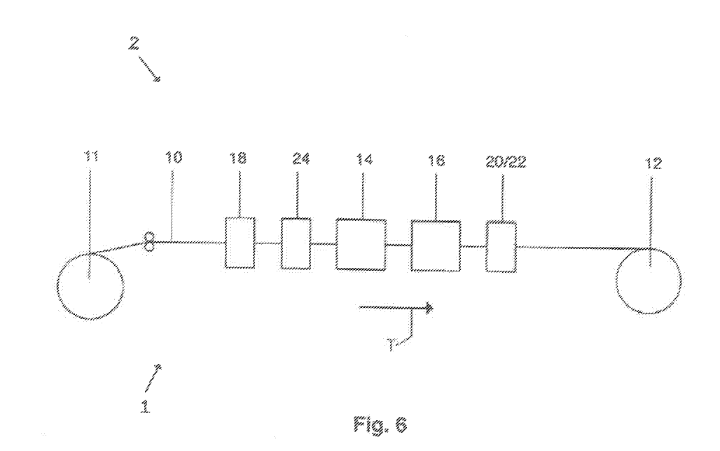

FIG. 6 shows an installation 1 according to the invention according to a further embodiment, which represents a variation of the embodiment of FIG. 5. In contrast—as viewed in the direction of transport T of the hot-rolled strip 10—a so-called. “scale breaker” 24 is arranged upstream of the pickling device 14, namely between the pickling device 14 and the first shear 18. Such a scale breaker 24, may be, according to its function, stretch leveler, which serves in a conventional manner for smoothing the surfaces of the hot-rolled strip 10, but without changing the thickness of the hot-rolled strip 10. Accordingly, when the scale breaker 24 is used, cold rolling of the hot-rolled strip 10 does not occur, and thus does not lead to a significant change in its material properties. This also applies in the same way to the stretch leveler 23 in the embodiment of FIG. 4.

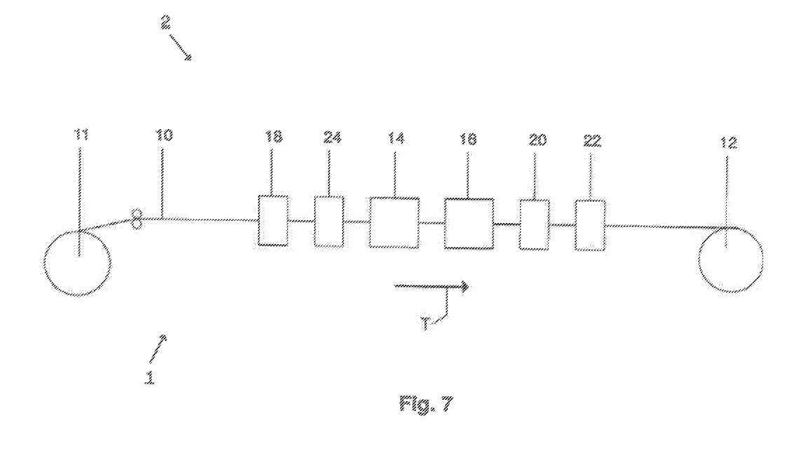

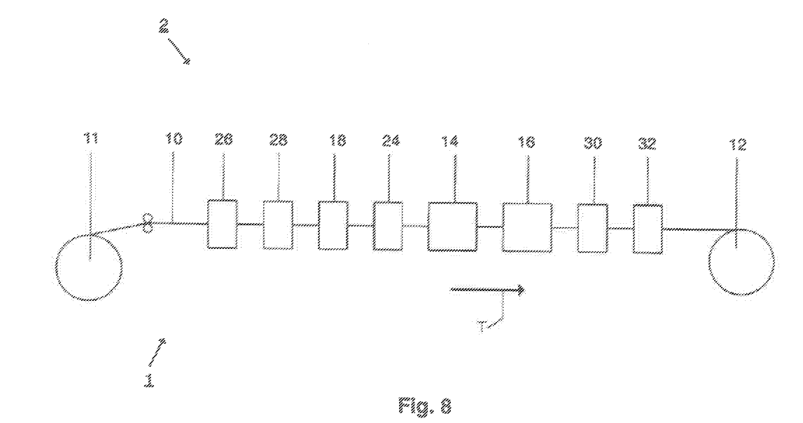

FIG. 7 shows an installation 1 according to the invention according to a further embodiment, as a variation of the embodiment of FIG. 6, according to which—as viewed in the direction of transport T of the hot-rolled strip 10—both a second coating device 20 and a skin pass mill 22 are arranged now downstream of the first coating device 16.

FIG. 8 shows an installation 1 according to the invention according to a further embodiment, with which a continuous operation of the treatment line 2 through the use of new coils is possible. For this purpose—as viewed in the direction of transport T of the hot-rolled strip 10—a connecting device 26 and a first looping pit 28 are arranged upstream of the pickling device 14. The connecting device 26 may be a welding device or an affixing device with which the margin regions of two different coils can be welded or affixed. If, when changing a coil whose beginning of the strip is to be connected to the end of the strip of a previous coil, this can be done thanks to the first looping pit 28, in which previously a sufficient amount or length of hot-rolled strip has been buffered or stored. In the same way—as viewed in the direction of transport T of the hot-rolled strip 10—a second looping pit 30 and a second shear 32 are arranged downstream of the first coating device. Thanks to these elements, it is possible to wind a batch of a coil of the hot-rolled strip 12 on the second coiling device 12 and to make a corresponding change at the second coiling device 12 for this purpose.

In the embodiment of FIG. 8, it is further provided to apply an oiling to the hot-rolled strip 10. For this purpose, an oiling machine 34 is arranged downstream of the second shear 32, by means of which can be applied to a top and/or bottom of the hot-rolled strip 10.

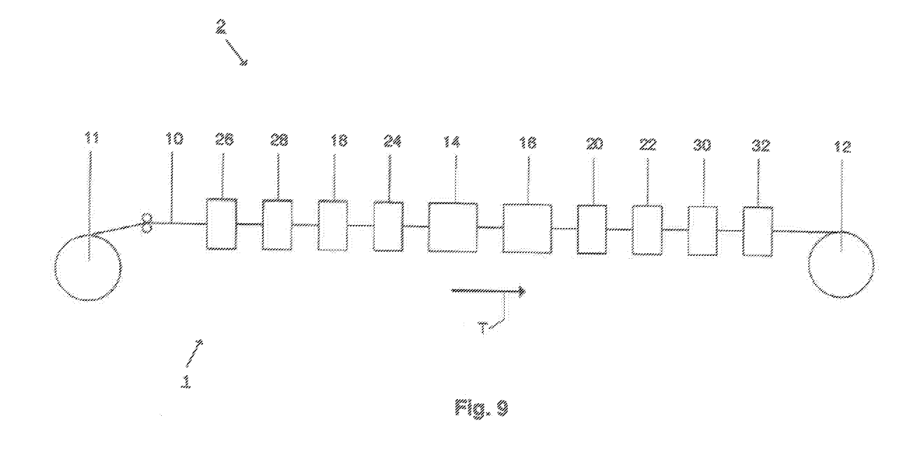

FIG. 9 shows an installation 1 according to the invention according to a further embodiment, which corresponds to a combination of the embodiments according to FIGS. 7 and 8. Thus, in the embodiment of FIG. 9, now a second coating device 20, a skin pass mill 22, a second looping pit 30, a second shear 32, and an oiling machine 34 are arranged downstream of the first coating device 16. To avoid repetition, reference is made to the corresponding explanations for FIGS. 7 and 8.

In comparison to the embodiment of FIG. 2, in the abovementioned embodiments according to FIGS. 3-9, in addition to the pickling device 14 and the first coating device 16, the following additional installation components are added:
first shear 18,
second coating device 20,
skin pass mill 22,
stretch leveler 24,
connecting device 26,
first looping pit 28,
second looping pit 30,
second shear 32, and/or
oiling machine 34.

With respect to these additional installation components, it is understood that a combination thereof with the embodiment of FIG. 2 is also possible in other ways than shown and explained by the illustration in FIGS. 3 to 9. Thus, it is possible to use these installation components in other combinations and possibly in a position in the treatment line 2 of installation 1, which are different from the illustrated drawing.

Finally, it should be noted that in all the above embodiments, the installation 1 can also be operated in such a way that the first coating device 16, by means of which normally, e.g., galvanizing is applied to the hot-rolled strip 10, is turned off. Accordingly, the hot-rolled strip 10 then passes through the treatment line 2, without the surfaces of the hot-rolled strip 10 being galvanized. In this way, when the first coating device 16 is turned off, a pickling of normal steel strips with pickling acid to produce a hot-rolled strip 10 with pickled and oiled surfaces can be realized by installation 1. Here, the oiled surfaces of the hot-rolled strip 10 are produced by means of the oiling machine 34.

What is claimed is:

1. A method for coating a scaled hot-rolled strip (10), at least comprising the steps of:
(i) providing a hot-rolled strip (10) in the form of a hot rolled preliminary strip,
(ii) preparing the surfaces of the hot-rolled strip (10), and
(iii) coating the hot-rolled strip (10) on at least one prepared surface thereof, wherein the coating is carried out at a temperature of ≤100° C. and immediately after the descaling of the hot-rolled strip (10),
characterized in
that, after step (iii), at least one further treatment step (iv) is carried out for the hot-rolled strip (10), in which the hot-rolled strip (10) is provided with an additional coating consisting of a plastic film lamination.

2. The method according to claim 1, characterized in that at step (ii) preparing the hot-rolled strip (10) is carried out by means of a pickling device (14)

3. The method according to claim 1, characterized in that at step (iii) coating of the hot-rolled strip (10) is carried out electrolytically or according to the principle of physical vapor deposition (PVD).

4. The method according to claim 1, characterized in that the hot-rolled strip (10) is trimmed at its side margins before step (ii).

5. The method according to claim 1, characterized in that the hot-rolled strip (10) is lead through a stretch leveler (24) before step (ii).

6. The method according to claim 1, characterized in that, in the further treatment step (iv), which is carried out after step (iii), the hot-rolled strip (10) is provided with an additional coating consisting of a chemical coating and/or of an oiling.

7. An installation (1) for coating a scaled hot-rolled strip (10), comprising a continuous treatment line (2), in which the hot-rolled strip (10) is moved in a direction of movement (T), wherein in the treatment line (2) a pickling device (14) for preparing the surfaces of the hot-rolled strip (10) and at least one first coating device (16) are provided,
wherein a coating can be applied to at least one prepared surface of the hot-rolled strip (10) by means of the first coating device (16),
wherein the first coating device (16) is configured such that the coating of the hot-rolled strip (10) takes place on at least one side thereof at a temperature of ≤100° C.,
characterized in,
that a second coating device (20) is provided which—as viewed in the direction of movement (T) of the hot-rolled strip (10)—is arranged downstream of the first coating device (16), wherein an additional coating consisting of a plastic film lamination is applied on at least one surface of the hot-rolled strip (10) by means of the second coating device (20).

8. The installation (1) according to claim 7, characterized in that—as viewed in the direction of movement (T) of the hot-rolled strip (10)—upstream of the pickling device (14) a first shear (18) is arranged in order to cut off side margins of the hot-rolled strip (10) in a defined manner.

9. The installation (1) according to claim 7, characterized in that a skin pass mill (22) is provided, which—as viewed in the direction of movement (T) of the hot-rolled strip (10)—is arranged downstream of the first coating device (16).

10. The installation (1) according to claim 7, characterized in that a stretch leveler (23) is provided, which—as viewed in the direction of movement (T) of the hot-rolled strip (10)—is arranged downstream of the first coating device (16).

11. The installation (1) according to claim 7, characterized in that a scale breaker (24) is provided, which—as viewed in the direction of movement (T) of the hot-rolled strip (10)—is arranged upstream of the pickling device (14).

12. The installation (1) according to claim 7, characterized in that a connecting device (26) and a first looping pit (28) are provided, each of which—as viewed in the direction of movement (T) of the hot-rolled strip (10)—are arranged upstream of the pickling device (14).

13. The installation (1) according to claim 12, characterized in that a second looping pit (30) and a second shear (32) are provided, each of which—as viewed in the direction of movement (T) of the hot-rolled strip (10)—are arranged downstream of the first coating device (16).

14. The installation (1) according to claim 9, characterized in that an oiling machine (34) is provided which—as viewed in the direction of movement (T) of the hot-rolled strip (10)—is arranged downstream of the second coating device (20).

15. Use of an installation (1) according to claim 7, in which the first coating device (16) remains offline so that the hot-rolled strip (10) is not coated by means of the first coating device (16).
